(19) United States
(12) Patent Application Publication
(10) Pub. No.: US 2026/0146895 A1
(43) Pub. Date: May 28, 2026

(54) INFRARED TERMOPILE SENSOR AND MANUFACTURING METHOD THEREFOR

(71) Applicant: SHANGHAI XINLONG SEMICONDUCTOR TECHNOLOGY CO., LTD., Pudong New Area, Shanghai (CN)

(72) Inventors: Xiaochen ZHANG, Shanghai (CN); Ruiping LI, Shanghai (CN)

(73) Assignee: SHANGHAI XINLONG SEMICONDUCTOR TECHNOLOGY CO., LTD., Pudong New Area, Shanghai (CN)

(21) Appl. No.: 19/121,205

(22) PCT Filed: Sep. 11, 2024
(86) PCT No.: PCT/CN2024/118155

§ 371 Date: Apr. 15, 2025

(30) Foreign Application Priority Data
Sep. 18, 2023 (CN) 202311195654.X

(51) Int. Cl. G01J 5/16; G01J 5/02; G01J 5/12; H10N 10/01

(52) U.S. Cl. CPC G01J 5/16; G01J 5/024; H10N 10/01; G01J 2005/123

(57) ABSTRACT

An IR thermopile sensor and a method of manufacturing the same. In the IR thermopile sensor, a substrate defines an annular first groove provided therein with a thermal conductivity enhancement layer made of an electrically conductive material. A plurality of thermocouple components are spaced apart from one another above an insulating layer and a support layer extend from above the thermal conductivity enhancement layer towards the inside of an internal annular wall of the first groove. The additionally included thermal conductivity enhancement layer can stabilize the temperature of cold ends of the thermocouple components and reflect IR radiation, helping maintain cold junctions at the same temperature as the ambient temperature. Thus, a temperature gradient can be more easily established across hot and cold ends, resulting in improved performance. The thermal conductivity enhancement layer can be made of a material, which is selected to make the present invention easy to implement in terms of structure. Additionally, since the only cost increase is caused by the thermal conductivity enhancement layer, facilitating commercial large-scale production. The insulating layer is disposed between the thermal conductivity enhancement layer and the thermocouple components and can reduce flicker noise in signals output from the IR thermopile sensor.

### TECHNICAL FIELD

The present invention relates to the field of temperature sensing technology and, in particular, to an infrared (IR) thermopile sensor and a method of manufacturing it.

### BACKGROUND

Infrared (IR) thermopile sensors are IR heat sensors. An IR thermopile sensor operates by converting received IR radiation into heat and then utilizing the Seebeck effect to generate electromotive force(s) from temperature difference(s) between two ends of at least one thermocouple pair connected in series. The intensity of the IR radiation can be calculated from voltage(s) measured across the ends of all the thermocouple pair(s). For example, when there is only one thermocouple, the voltage generated by the Seebeck effect can be expressed as:

$$V = {\int }_{{T}_{1}}^{{T}_{2}} ( {S}_{A} ( T ) - {S}_{B} ( T ) ) dT ,$$

where SA and SB are the Seebeck coefficients of the materials of the two arms of the thermocouple. If SA and SB are considered to not to vary with temperature, then V=(SA−SB)ΔT, where ΔT represents the temperature difference between the ends of the thermocouple. IR thermopile sensors are manufactured using the micro-electro-mechanical system (MEMS) process, optionally in combination with the CMOS process, and widely used in non-contact temperature measurement, NDIR gas analysis, thermal imaging and many other applications. As can be seen from the above, thermopile sensors provide a variety of advantages including simple operating principles, ease of use (without no need for cryogenicity, a waveform chopper or a bias voltage, a wide operating spectral range, and non-contact measurement) and low cost (their manufacturing is compatible with the CMOS process). Therefore, they account for a large share in the IR sensor market.

Although IR thermopile sensors are very popular in temperature measurement, low-cost gas analysis, low-resolution, thermal imaging and many other fields, they are challenged by potent competitors in other sectors, such as pyroelectric detectors in motion detection and high-end gas analysis, which provide faster response and higher sensitivity, and micro-bolometer arrays and cryogenic photon detectors in thermal imaging, which offer higher accuracy and higher resolution. Therefore, there exists a continuing need in the art for further performance improvements of IR thermopile sensors.

Although various attempts have been made so far in China and abroad for improving the performance of IR thermopile sensors, they focus on the design of materials, membranes and structures with high IR absorption, or on dimensional and structural optimization of IR thermopile sensors. The resulting high-performance IR thermopile sensors usually suffer from high cost, less utility, unsuitability for mass production and other problems, and are therefore not well accepted in the market.

### SUMMARY

It is an objective of the present invention to provide an infrared (IR) thermopile sensor and a method of manufacturing the sensor, which overcome the problem that conventional high-performance IR thermopile sensors are not well accepted in the market due to high cost, inadequate utility and unsuitability for mass production.

To this end, the present invention provides an IR thermopile sensor including: a substrate defining an annular first groove provided therein with a thermal conductivity enhancement layer, wherein the thermal conductivity enhancement layer is made of an electrically conductive material; a support layer covering the substrate internal to an internal annular wall of first groove; an insulating layer covering the thermal conductivity enhancement layer; a plurality of thermocouple components all spaced apart from one another above the insulating layer and the support layer and extending from above the thermal conductivity enhancement layer towards the inside of the internal annular wall; and an absorption component covering the support layer and all the thermocouple components.

Optionally, the thermal conductivity enhancement layer may be made of Al.

Optionally, the thermal conductivity enhancement layer may have a thickness greater than 2 μm and a width greater than 10 μm. Alternatively, the thermal conductivity enhancement layer may have a width greater than a cold junction width of the thermocouple components.

Optionally, the insulating layer may be made of silicon carbide or aluminum nitride, wherein the insulating layer covers only the thermal conductivity enhancement layer. Alternatively, the insulating layer may be made of silicon oxide or silicon nitride, wherein the insulating layer covers both the thermal conductivity enhancement layer and the support layer.

Optionally, each thermocouple component may include: a first thermocouple arm residing above the insulating layer and the support layer and extending from above the thermal conductivity enhancement layer towards the inside of the internal annular wall; an intermediate dielectric layer residing on the first thermocouple arm; a second thermocouple arm residing on the intermediate dielectric layer; and a connecting post extending through the intermediate dielectric layer, with its end proximal to the first thermocouple arm being in contact with the first thermocouple arm and with its end proximal to the second thermocouple arm being in contact with the second thermocouple arm.

Optionally, the absorption component may include: a polycrystalline silicon layer residing on the support layer, the polycrystalline silicon layer internal to and in contact with all the first thermocouple arms, the polycrystalline silicon layer covered by the intermediate dielectric layer; a light-interference and heat-guide layer residing on the support layer, the light-interference and heat-guide layer internal to all the first thermocouple arms, the light-interference and heat-guide layer surrounded by the polycrystalline silicon layer; an IR absorption layer covering the light-interference and heat-guide layer, the second thermocouple arms and the intermediate dielectric layer over the polycrystalline silicon layer; and an enhanced absorption layer covering the IR absorption layer over the polycrystalline silicon layer and the light-interference and heat-guide layer.

Optionally, the first groove may be a circular, elliptical or polygonal ring, wherein the light-interference and heat-guide layer is provided as a combination of a plurality of petal-like elements, which are centered at a center of the first groove and each has a width gradually increasing in a direction away from the center.

Additionally, the light-interference and heat-guide layer may be spaced from the thermocouple components at a distance less than 10 μm and has a thickness of 100 nm to 1 μm.

Additionally, the light-interference and heat-guide layer may be made of a metal material or polycrystalline silicon.

Optionally, the substrate may have a front side and an opposing backside, wherein the substrate internal to the internal annular wall of the first groove defines a cavity in the form of a through opening extending through the substrate and exposing the support layer on the front side, the cavity having an opening size at the backside equal to a width defined by an internal annular wall of the thermal conductivity enhancement layer and an opening size at the front side less than a width defined by the internal annular wall of the first groove. Alternatively, the cavity may be in the form of a blind cavity on the front side along with the first groove, wherein the cavity is closed by the support layer, and has a larger depth than the first groove and an opening size less than a width defined by the internal annular wall of the first groove.

Additionally, the thermal conductivity enhancement layer may be spaced from the cavity at a distance greater than 5 μm.

Additionally, the absorption component over the cavity may be evenly provided therein with a plurality of through openings extending through the support layer, the insulating layer and the absorption component.

In another aspect, the present invention provides a method of manufacturing the IR thermopile sensor as defined above, which includes the steps of: providing a substrate defining an annular first groove, wherein a support layer is formed on the substrate internal to an internal annular wall of the first groove; forming a thermal conductivity enhancement layer and an insulating layer, the thermal conductivity enhancement layer filling up the first groove, the insulating layer residing on the thermal conductivity enhancement layer, wherein the thermal conductivity enhancement layer is made of an electrically conductive material; and forming a plurality of thermocouple components and an absorption component, all the thermocouple components spaced apart from one another above the insulating layer and the support layer and extending from above the thermal conductivity enhancement layer towards the inside of the internal annular wall, the absorption component covering the support layer and all the thermocouple components.

Optionally, after the plurality of thermocouple components and the absorption component are formed, the method may further include: forming a cavity in the substrate, which exposes the support layer.

Compared with the prior art, the present invention offers the benefits as follows:

1. The thermal conductivity enhancement layer is added, which can stabilize the temperature of the cold ends and reflect IR radiation, helping maintain the cold junctions at the same temperature as the ambient temperature. Thus, a temperature gradient can be more easily established across the hot and cold ends, resulting in increased responsivity and improved performance of the IR thermopile sensor. As the electrically conductive material can be selected as any of many commonly-used materials (e.g., Al), the IR thermopile sensor of the invention is easy to implement in terms of structure. Additionally, since the only cost increase is caused by the thermal conductivity enhancement layer (which can be ignored), the aforementioned performance improvement is achieved while not causing any increase in cost, facilitating commercial large-scale production.

2. The insulating layer between the thermal conductivity enhancement layer and the thermocouple components can reduce flicker noise in signals output from the IR thermopile sensor.

3. The interfering and heat-guide layer in the absorption component enables interference and coupling of reflected light with incident light, resulting in improved IR absorption performance. Further, the light-interference and heat-guide layer may define a particular pattern, which enables it to also guide heat to concentrate it at the hot ends of the thermocouples, helping reduce heat losses that may otherwise occur due to uniform heat conduction across, and heat radiation of, the absorption region. This means that the temperature of the hot junctions can rise at a faster rate and to a higher value at a given level of radiation intensity, contributing to increased responsivity and a shorter response time.

4. The thermal conductivity enhancement layer and the interference and heat guide layer help provide the sensor with a good electromagnetic environment with reduced environmental noise. Stabilizing the cold ends at the ambient temperature also contributes to reducing thermal noise, helping reduce equivalent noise power and improve detectivity.

5. The method is based on the MEMS process and compatible with the CMOS process and does not require the use of any additional reticle. The only thing added is the formation and filling of the first groove, which results in a significant performance improvement almost without causing any increase in cost. Therefore, the present invention is more cost-effective and conducive to facilitate commercial large-scale production.

### BRIEF DESCRIPTION OF THE DRAWINGS

FIG. 1 is a schematic top view of an infrared (IR) thermopile sensor according to a first embodiment of the present invention.

FIG. 2 is a schematic cross-sectional view taken along line AA′ of FIG. 1.

FIG. 3 is a schematic flowchart of a method of manufacturing the IR thermopile sensor according to the first embodiment of the present invention.

FIG. 4 is a schematic diagram showing the structure of a substrate provided in accordance with the first embodiment of the present invention.

FIG. 5 is a schematic diagram showing a structure resulting from the formation of a thermal conductivity enhancement layer according to the first embodiment of the present invention.

FIG. 6 is a schematic diagram showing a structure resulting from the implantation of n-type ions according to the first embodiment of the present invention.

FIG. 7 is a schematic diagram showing a structure resulting from the formation of a polycrystalline silicon layer according to the first embodiment of the present invention.

FIG. 8 is a schematic diagram showing a structure resulting from the formation of an intermediate dielectric layer according to the first embodiment of the present invention.

FIG. 9 is a schematic diagram showing a structure resulting from the formation of second thermocouple arms according to the first embodiment of the present invention.

FIG. 10 schematically illustrates a first example of a light-interference and heat-guide layer according to the first embodiment of the present invention.

FIG. 11 schematically illustrates a second example of the light-interference and heat-guide layer according to the first embodiment of the present invention.

FIG. 12 is a schematic diagram showing a structure resulting from the formation of an IR absorption layer according to the first embodiment of the present invention.

FIG. 13 is a schematic diagram showing a structure resulting from the formation of a thermal conductivity enhancement layer according to the first embodiment of the present invention.

FIG. 14 is a schematic top view of an IR thermopile sensor according to a second embodiment of the present invention.

FIG. 15 is a schematic cross-sectional view of the second embodiment of the present invention taken along line AA′ of FIG. 14.

In these figures, 100 denotes a substrate; 101, a cavity; 110, a support layer; 120, a thermal conductivity enhancement layer; 130, an insulating layer; 200, a thermocouple component; 210, a first thermocouple arm; 211, a first opening; 220, a connecting post; 230, a second thermocouple arm; 240, an intermediate dielectric layer; 241, a second opening; 300, an absorption component; 310, a polycrystalline silicon layer; 320, a light-interference and heat-guide layer; 330, an IR absorption layer; 340, an enhanced absorption layer; and 400, a through opening.

### DETAILED DESCRIPTION

An infrared (IR) thermopile sensor and a method of manufacturing the sensor according to the present invention will be described in greater detail below. The following more detailed description of the invention is made with reference to the accompanying drawings, which illustrate particular embodiments thereof. It will be understood that those skilled in the art can make changes to the invention disclosed herein while still obtaining the beneficial results thereof. Therefore, the following description shall be construed as being intended to be widely known by those skilled in the art rather than as limiting the invention.

For the sake of clarity, not all features of an actual implementation are described in this specification. In the following, description and details of well-known functions and structures are omitted to avoid unnecessarily obscuring the invention. It should be appreciated that in the development of any such actual implementation, numerous implementation-specific decisions must be made to achieve specific goals of the developers, such as compliance with system-related and business-related constrains, which may vary from one implementation to another. Moreover, it should be appreciated that such a development effort might be complex and time consuming, but would nevertheless be a routine undertaking for those of ordinary skill in the art.

Objects and features of the present invention will become more apparent upon reading the following more detailed description with reference to the accompanying drawings, which illustrate particular embodiments thereof. Note that the figures are provided in a very simplified form not necessarily drawn to exact scale for the only purpose of helping in describing the embodiments in a convenient and clear way.

The current research effort in China and abroad to develop IR thermopile sensors with improved performance often focuses on treating (e.g., “blackening”) the surface of an absorption region to enhance its IR absorption efficiency through adding a material such as black silicon or a metal black to the surface. Due to a large bandgap width, black silicon absorbs radiation only in a limited wavelength range. Although metal blacks exhibit high absorptivity, as they require the use of materials, equipment and processes that are not commonly used in the CMOS process, which imposes stringent requirements on the manufacturing process and leads to high cost. There are also some improvement solutions, such as the so-called nano-forests that utilize the surface plasmon effect. However, these are also associated with many problems, such as a complex process (involving a large number of steps), high difficulty, high equipment cost, poor reliability, etc. These new materials and processes are not well accepted in the market because their limited performance improvements and significant cost increases make them less attractive compared to the conventional IR thermopile sensors which are available at very low price due to large production capacity and intense market competition in spite of suboptimal performance. Therefore, there exists a need for IR thermopile sensors, which exhibit significantly improved performance while allowing satisfactory cost control.

It will be well recognized that metal materials have higher thermal conductivity than silicon or other semiconductor materials. For example, aluminum, one of the commonly used metal materials, exhibits higher thermal capacity, which means better thermal conduction performance and better temperature stability with a given structure and dimensions for IR thermopile sensor applications. For a given structure, thermal conduction performance is also related to its dimensions. The thermal conductivity of a one-dimensional flat wall can be modeled as Q=kAT/L, or Q=T/R, where k is the thermal conductivity of the structure, A is the area of the flat wall, L is the thickness of the flat wall, T is a temperature difference measured normally to the flat wall, and R is the thermal resistance and satisfies R=kA/L. As can be seen, the thermal conductivity is inversely proportional to the thickness of the structure, along which heat is conducted, and the thermal conductivity is normally proportional to the cross-sectional area of the structure. Therefore, an insulating film between a thermal conductivity enhancement layer and the cold end is desired to be as thin as possible (to minimize the longitudinal thermal resistance), and a film between the two thermocouple arms is also desired to be as thin as possible (to minimize the transverse thermal resistance).

An output voltage V_S of an IR thermopile sensor can be expressed as V_S=N (S_A−S_B) T, N is a logarithm of a thermocouple component therein, S_A is the Seebeck coefficient of the material of a first thermocouple arm, S_B is the Seebeck coefficient of the material of a second thermocouple arm, and T is an average temperature difference. As can be seen from the expression, increasing the average temperature difference T between the hot and cold ends of the thermocouple component can directly augment the output signal of the IR thermopile sensor. Responsivity R_s of the IR thermopile sensor is defined as a ratio of the output voltage V_S to incident radiation power P, i.e., R_s=V_s/P. Thus, augmenting the output signal of the IR thermopile sensor can increase its responsivity. Additionally, equivalent noise power NEP of the IR thermopile sensor is defined as the incident radiation power P, at which the resulting output voltage V_S is equal to a noise voltage V_nosie of the IR thermopile sensor, i.e., NEP=V_nosie/R_s. This indicates that a lower noise voltage results in reduced equivalent noise power. Detectivity D of the IR thermopile sensor is defined as the reciprocal of the equivalent noise power NEP, i.e., D=1/NEP, indicating that a lower noise voltage results in higher detectivity.

On this basis, the present invention provides an IR thermopile sensor including a substrate. An annular first groove is formed in the substrate. A thermal conductivity enhancement layer is provided in the first groove, and the substrate is provided thereon with a support layer, an insulating layer, a plurality of thermocouple components and an absorption component. The support layer covers the substrate internal to an internal annular wall of the first groove, and the insulating layer covers the thermal conductivity enhancement layer. All the thermocouple components are spaced apart from one another above the insulating layer and the support layer and extend from above the thermal conductivity enhancement layer towards the internal side of the internal annular wall. The absorption component covers the support layer and all the thermocouple components. The thermal conductivity enhancement layer is made of an electrically conductive material.

According to the present invention, the thermal conductivity enhancement layer stabilizes the temperature of the cold ends of the thermocouple components and serves to reflect IR radiation, helping maintain the temperature of the cold junctions (ends) of the thermocouple components equal to the ambient temperature. This facilitates the establishment of a temperature gradient across the hot and cold ends of the thermocouple components, which helps improve responsivity and performance of the IR thermopile sensor. As the electrically conductive material can be selected as any of many commonly-used materials (e.g., aluminum), the IR thermopile sensor of the invention is easy to implement in terms of structure. Additionally, since the only cost increase is caused by the thermal conductivity enhancement layer (which can be ignored), the aforementioned performance improvement is achieved while not causing any increase in cost, facilitating commercial large-scale production.

### Example 1

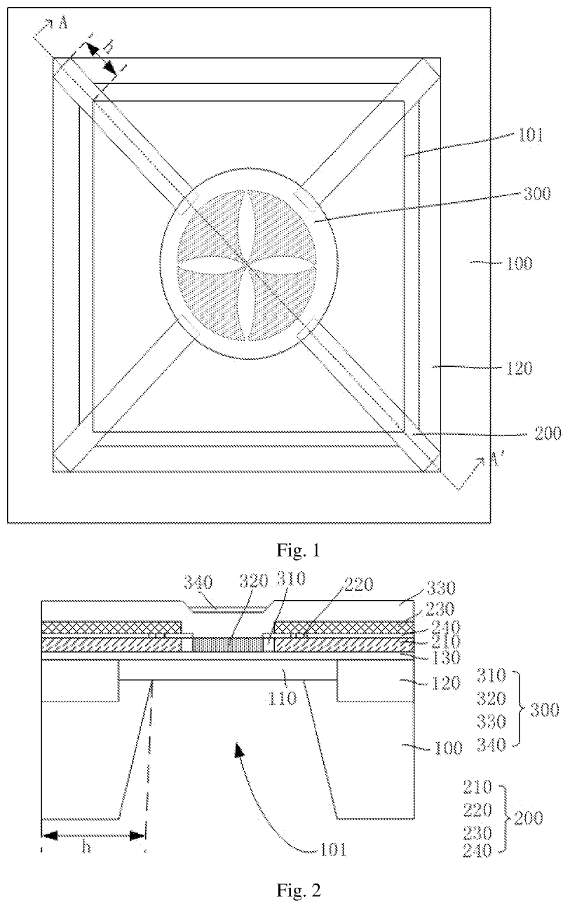

As shown in FIGS. 1 and 2, in a first embodiment of the present invention, there is provided an IR thermopile sensor including a substrate 100. An annular first groove is formed in the substrate 100. The substrate 100 internal to an internal annular wall of the first groove defines a cavity 101, the cavity 101 is in the form of a through opening internal to the first groove. A thermal conductivity enhancement layer 120 is provided in the first groove. The substrate 100 is provided thereon with a support layer 110, an insulating layer 130, a plurality of thermocouple components 200 and an absorption component 300. The support layer 110 resides above the cavity 101 and covers outer edges of the cavity 101 and the substrate 100 internal to the internal annular wall. The insulating layer 130 covers the thermal conductivity enhancement layer 120, and all the thermocouple components 200 are spaced apart from one another above the insulating layer 130 and the support layer 110. Moreover, all the thermocouple components 200 extend from above the thermal conductivity enhancement layer 120 towards the internal side of the internal annular wall. The absorption component 300 covers the support layer 110 and all the thermocouple components 200. The thermal conductivity enhancement layer 120 is made of an electrically conductive material. Each thermocouple component 200 defines cold and hot ends in its direction of extension. The cold end is located above the thermal conductivity enhancement layer 120, and the hot end is located internal to the internal annular wall and connected to the absorption component 300.

In this embodiment, the thermal conductivity enhancement layer 120 exhibits both high thermal conductivity and high thermal capacity, helping stabilize the temperature of the cold ends (junctions) of the thermocouple components 200. Moreover, it also serves to reflect IR radiation, making the cold ends of the thermocouple components 200 easier to maintain the same temperature as the ambient temperature. This facilitates the establishment of a temperature gradient across the hot and cold ends of the thermocouple components, thereby improving the performance of the IR thermopile sensor and facilitating its mass production without causing a significant increase in cost. Further, the insulating layer 130 is disposed between the thermal conductivity enhancement layer 120 and the thermocouple components 200, the insulating layer 130 helps reduce flicker noise in signals output from the IR thermopile sensor.

Specifically, the substrate 100 may be made of monocrystalline silicon, the substrate 100 may be made of any suitable shape as required in practical applications, such as square, rectangular or circular. This embodiment is not limited to any particular material or shape of the substrate 100.

The substrate 100 has a front side and an opposing backside. The cavity 101 extends through the substrate 100. An opening size of the cavity 101 at the backside is equal to a width defined by an internal annular wall of the thermal conductivity enhancement layer 120. An opening size of the cavity 101 at the front side is less than the width defined by the internal annular wall of the thermal conductivity enhancement layer 120.

The support layer 110 is provided on the front side of the substrate 100. The support layer 110 covers the opening of the cavity 101 at the front side, the outer edges of the cavity 101 and the front side internal to the internal annular wall. The support layer 110 is provided to support the components above it, such as the insulating layer 130, the thermocouple components 200 and the absorption component 300. The support layer 110 may be a silicon oxide layer. Alternatively, it may consist of a silicon oxide layer and a silicon nitride layer, with the silicon oxide layer being disposed between the silicon nitride layer and the front side. The support layer 110 has a thickness of 200 nm to 500 nm.

The first groove is provided at the front side of the substrate 100. The first groove extends through the support layer 110 and its bottom is located within the substrate 100. The first groove is in the shape of a ring, such as a rectangular, circular, elliptical or otherwise polygonal ring. The first groove has a depth greater than 2 μm and a width greater than 10 μm. Preferably, the width is greater than a cold junction width h of the thermocouple components 200.

The thermal conductivity enhancement layer 120 is provided in the first groove, the thermal conductivity enhancement layer 120 fills up the first groove. The thermal conductivity enhancement layer 120 is made of an electrically conductive material, such as a metal material. Particular examples may include metals commonly used in the CMOS process, such as Al, Ti and W, and compounds with high thermal conductivity, such as silicon carbide. Preferably, the thermal conductivity enhancement layer 120 is made of Al that exhibits both higher thermal conductivity and higher thermal capacity than other electrically conductive materials, meaning that the use of Al can result in both improved thermal conduction performance and increased temperature stability with a given structure and dimensions. Thus, the thermal conductivity enhancement layer 120 can stabilize the temperature of the cold ends (junctions) of the thermocouple components 200. Additionally, it is able to reflect IR radiation, making the cold ends of the thermocouple components 200 easier to maintain the same temperature as the ambient temperature. This facilitates the establishment of a temperature gradient across the hot and cold ends, thereby improving the performance of the IR thermopile sensor and facilitating its mass production without causing a significant cost increase.

The thermal conductivity enhancement layer 120 has a thickness greater than 2 μm and a width (delimited by the internal annular wall of the first groove) greater than 10 μm. Preferably, the width of the thermal conductivity enhancement layer 120 is greater than the cold junction width h. The thermal conductivity enhancement layer 120 is spaced from the cavity 101 at a distance greater than 5 μm.

Optionally, an adhesion enhancement film may be formed between the thermal conductivity enhancement layer 120 and the insulating layer 130, which covers the thermal conductivity enhancement layer 120 and serves to enhance adhesion between the thermal conductivity enhancement layer 120 and the insulating layer 130.

The insulating layer 130 may be made of a material with high thermal insulation properties, such as undoped silicon carbide (SiC), aluminum nitride (AlN) or the like. In this case, the insulating layer 130 may have a thickness of 50 nm to 500 nm. Alternatively, the insulating layer 130 may be made of an ordinary insulating material, such as silicon oxide or silicon nitride. The insulating layer 130 between the thermal conductivity enhancement layer and the cold ends is desired to be as thin as possible (in order to minimize longitudinal thermal resistance). Accordingly, the thickness of the insulating layer 130 may be in the range of 20 nm to 200 nm.

In case of the insulating layer 130 being made of a material with high thermal insulation properties, the insulating layer 130 may cover only the adhesion enhancement film on the thermal conductivity enhancement layer 120 due to its small transverse thermal resistance. In case of the insulating layer 130 being made of silicon oxide or silicon nitride, the insulating layer 130 may cover both the adhesion enhancement film on the thermal conductivity enhancement layer 120 and the support layer 110 internal to the internal annular wall due to its large transverse thermal resistance and small longitudinal thermal resistance.

The thermocouple components 200 are elongate in shape, and there are an even number of pairs of thermocouple components 200. In one embodiment of the present invention, there are 4 pairs of thermocouple components 200, and the cold ends of each pair of thermocouple components 200 are located at the intersection of two adjacent sides of a rectangular ring. In an alternative embodiment, the cold ends of each pair of thermocouple components 200 may be located on a respective one of the sides of the rectangular ring.

Each thermocouple component 200 includes a first thermocouple arm 210, an intermediate dielectric layer 240, a connecting post 220 and a second thermocouple arm 230. The first thermocouple arm 210 is located above the insulating layer and the support layer. The first thermocouple arm 210, the intermediate dielectric layer 240 and the second thermocouple arm 230 are all elongate in shape. The first thermocouple arm 210, the intermediate dielectric layer 240 and the second thermocouple arm 230 are sequentially stacked on the insulating layer 130. The connecting post 220 extends through the intermediate dielectric layer 240, with its end proximal to the first thermocouple arm 210 being in contact with the first thermocouple arm 210 and with its end proximal to the second thermocouple arm 230 being in contact with the second thermocouple arm 230. An end of the first thermocouple arm 210 is located above the thermal conductivity enhancement layer 120 and serves as the cold end of the thermocouple component 200, and ends of the first thermocouple arm 210 and the second thermocouple arm 230 located away from the thermal conductivity enhancement layer 120 provide the hot end of the thermocouple component 200.

When the insulating layer 130 is made of a material with high thermal insulation properties, the first thermocouple arm 210 is located above both the insulating layer 130 and the support layer 110. In case of the insulating layer 130 being made of silicon oxide or silicon nitride, the first thermocouple arm 210 is located only above the insulating layer 130.

The first thermocouple arm 210 is made of polycrystalline silicon doped with n-type ions. This enables the insulating layer 130 to reduce flicker noise in signals output from the IR thermopile sensor. The first thermocouple arm 210 has a thickness of 300 nm to 5 μm. The intermediate dielectric layer 240 is made of a material with low thermal insulation properties, such as silicon oxide. The intermediate dielectric layer 240 between the two thermocouple arms is desired to be as thin as possible (in order to maximize transverse thermal resistance). Accordingly, the thickness of the intermediate dielectric layer 240 may be in the range of 20 nm to 500 nm. The connecting post 220 provides an interconnection between the first thermocouple arm 210 and the second thermocouple arm 230. Therefore, it is desired to provide good ohmic contact. It may be a composite film, such as TiN/Ti/W. The second thermocouple arm 230 may be made of a metal (e.g., Al, Ti, W, etc.), or polycrystalline silicon doped with n-type ions. The second thermocouple arm 230 has a thickness of 100 nm to 1 μm.

The absorption component 300 includes a polycrystalline silicon layer 310, a light-interference and heat-guide layer 320, an IR absorption layer 330 and an enhanced absorption layer 340. The polycrystalline silicon layer 310 and the light-interference and heat-guide layer 320 both reside on the insulating layer 130, or on the support layer 110 (i.e., when the insulating layer 130 is made of a material with high thermal insulation properties, the polycrystalline silicon layer 310 and the light-interference and heat-guide layer 320 both reside on the support layer 110; or when the insulating layer 130 is made of silicon oxide or silicon nitride, the polycrystalline silicon layer 310 and the light-interference and heat-guide layer 320 both reside on the insulating layer 130). The polycrystalline silicon layer 310 and the light-interference and heat-guide layer 320 are both located internal to all the thermocouple components 200, and the polycrystalline silicon layer 310 surrounds the light-interference and heat-guide layer 320. The other ends of the first thermocouple arms 210 may be in contact with the polycrystalline silicon layer 310. In this case, the intermediate dielectric layer 240 also covers the polycrystalline silicon layer 310, and the IR absorption layer 330 covers the light-interference and heat-guide layer 320, the second thermocouple arms 230 and the intermediate dielectric layer 240 on the polycrystalline silicon layer 310. The enhanced absorption layer 340 covers the IR absorption layer 330 on the polycrystalline silicon layer 310 and the light-interference and heat-guide layer 320.

The polycrystalline silicon layer 310 and the light-interference and heat-guide layer 320 are arranged in the same layer, the polycrystalline silicon layer 310 is located between the light-interference and heat-guide layer 320 and the first thermocouple arms 210. Since the light-interference and heat-guide layer 320 overlies the support layer 110 and underlies the IR absorption layer 330, the light-interference and heat-guide layer 320 is desired to be shaped in a particular manner to provide optimal performance. The light-interference and heat-guide layer 320 exhibits both high thermal conductivity and high specific heat capacity. Therefore, it can collect and guide heat to concentrate it at the hot ends of the thermocouple components 200, helping reduce heat losses that may otherwise occur due to uniform heat conduction across, and heat radiation of, the absorption component 300. Accordingly, the light-interference and heat-guide layer 320 may be provided as a combination of a plurality of petal-like elements, which are centered at a center of the first groove and each has a width gradually increasing in a direction away from the center. For example, they may be provided as fan-like elements each having its vertex located at said center, as shown in FIG. 10. In an alternative example, they may be provided as triangular or otherwise inwardly tapered elements each having its vertex located at the center, as shown in FIG. 11. Moreover, the light-interference and heat-guide layer 320 is disposed in close proximity to the first thermocouple arms 210. That is, the petal-like elements are as close as possible to the first thermocouple arms 210.

Each petal-like element in the light-interference and heat-guide layer 320 is spaced from the nearest one of the thermocouple components 200 at a distance less than 10 μm. Preferably, the distance between the light-interference and heat-guide layer 320 and the first thermocouple arms 210 is less than 5 μm, and is desired to be as small as possible, in order to bring the light-interference and heat-guide layer 320 as close as possible to the first thermocouple arms 210 to minimize escape of heat from the hot ends. The light-interference and heat-guide layer 320 has a thickness of 100 nm to 1 μm, and an excessively large or small thickness thereof may adversely affect its reflection properties.

The light-interference and heat-guide layer 320 may be made of a metal material (e.g., Al, Ti, W or another metal commonly used in the CMOS process), a high reflectivity material or a film (e.g., a polycrystalline silicon, silicon carbide or all-dielectric reflective film). In the case of the light-interference and heat-guide layer 320 being made of a metal material, it is preferably made of Al, which allows coupling of reflected light with incident light, thus enhancing IR absorptivity of the IR absorption layer 330. The metal material has both high thermal conductivity and high specific heat capacity (among such metals, Al exhibits the highest thermal conductivity and highest specific heat capacity) and therefore can collect and guide heat to facilitate its concentration at the hot ends of the thermocouple components 200, reducing heat losses that may otherwise occur due to heat conduction across, and heat radiation of, the absorption components 300.

The polycrystalline silicon layer 310 is an undoped polycrystalline silicon layer. The polycrystalline silicon layer 310 has the same thickness as the first thermocouple arms 210. The IR absorption layer 330 may a silicon nitride layer, or a silicon oxide/silicon nitride composite film, with a thickness greater than 1 μm. In alternative embodiments, the IR absorption layer 330 may be an enhanced absorption layer, such as a blackened absorption layer, or a nano-forest structure. The enhanced absorption layer 340 is provided to reduce reflection, and may be made of any of TiN, TiO₂, SiN, SiO, SiO₂, SiC and Al₂O₃, or a combination thereof. The enhanced absorption layer 340 has a thickness of 20 nm to 50 nm.

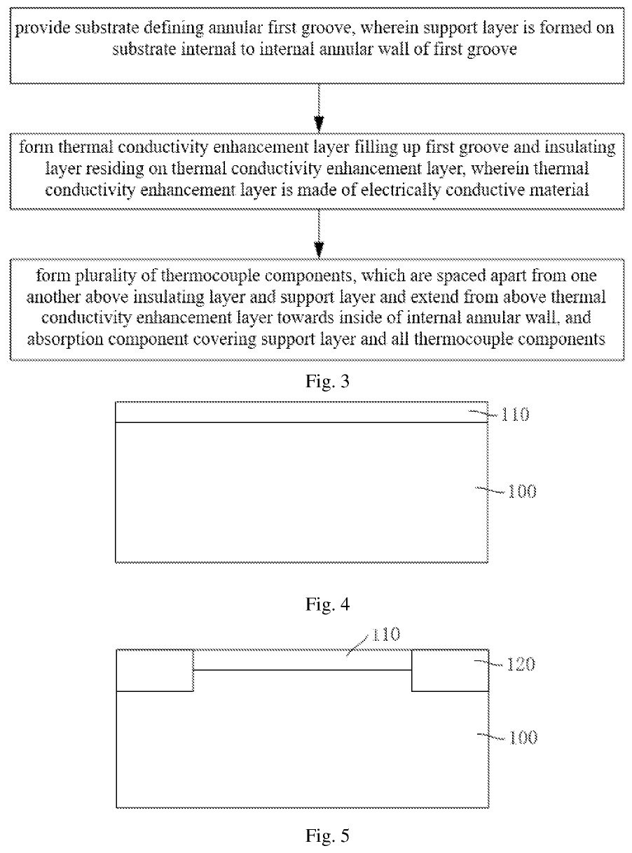

As shown in FIG. 3, the IR thermopile sensor of the present embodiment may be made according to a method, which is based on the conventional CMOS process and materials used herein, and is compatible with the conventional IR thermopile sensor process. The method includes the steps as follows.

Step S11: Provide a substrate 100. An annular first groove is formed in the substrate 100, and a support layer 110 on the substrate 100 internal to an internal annular wall of the first groove.

Step S12: Form a thermal conductivity enhancement layer 120 and an insulating layer 130. The thermal conductivity enhancement layer 120 fills up the first groove, and the insulating layer 130 resides on the thermal conductivity enhancement layer 120. The thermal conductivity enhancement layer 120 is made of an electrically conductive material.

Step S13: Form a plurality of thermocouple components 200 and an absorption component 300. All the thermocouple components 200 are spaced apart from one another above the insulating layer 130 and the support layer 110, the thermocouple components 200 extend from above the thermal conductivity enhancement layer 120 towards the internal side of the internal annular wall. The absorption component 300 covers the support layer 110 and all the thermocouple components 200.

The method is described in detail below with reference to FIGS. 1 to 13.

At first, in step S11, a substrate 100 is provided. An annular first groove is formed in the substrate 100, and a support layer 110 on the substrate 100 internal to an internal annular wall of the first groove.

Specifically, this step includes the sub-steps as follows.

As shown in FIG. 4, first of all, the substrate 100 is provided, the substrate 100 has a front side and an opposing backside. The support layer 110 is then deposited on the front side using a plasma-enhanced chemical vapor deposition (PECVD) or low-pressure chemical vapor deposition (LPCVD) process. The support layer 110 may be a silicon oxide layer, or may consist of a silicon oxide layer and a silicon nitride layer. The support layer 110 has a thickness of 200 nm to 500 nm.

As shown in FIG. 5, an etching process is then carried out to form the first groove. The first groove is annular and extends through the support layer 110. The etching process stops in the substrate 100. The first groove serves as a window enabling the formation of the thermal conductivity enhancement layer 120. The first groove has a width greater than 10 μm and a depth greater than 2 μm.

After that, in step S12, the thermal conductivity enhancement layer 120 and the insulating layer 130 are formed. The thermal conductivity enhancement layer 120 fills the first groove, and the insulating layer 130 resides on the thermal conductivity enhancement layer 120. The thermal conductivity enhancement layer 120 is made of an electrically conductive material.

Specifically, this step includes the sub-steps as follows.

At first, referring to FIG. 5, the electrically conductive material is deposited onto the surface of the support layer 110 and into the first groove. The electrically conductive material deposited above the surface of the support layer 110 is etched away, as well as unwanted portions thereof in the first groove, thus forming the thermal conductivity enhancement layer 120. The resulting thermal conductivity enhancement layer 120 has a width greater than 10 μm and a thickness greater than 2 μm. The thermal conductivity enhancement layer 120 may be made of a metal commonly used in the CMOS process, such as Al, Ti or W, or a compound with high thermal conductivity, such as silicon carbide. In the present embodiment, the thermal conductivity enhancement layer 120 is an Al layer.

Optionally, an adhesion enhancement film (not shown) may be deposited on the thermal conductivity enhancement layer 120 to enhance its adhesion. The adhesion enhancement film may be a TiN layer.

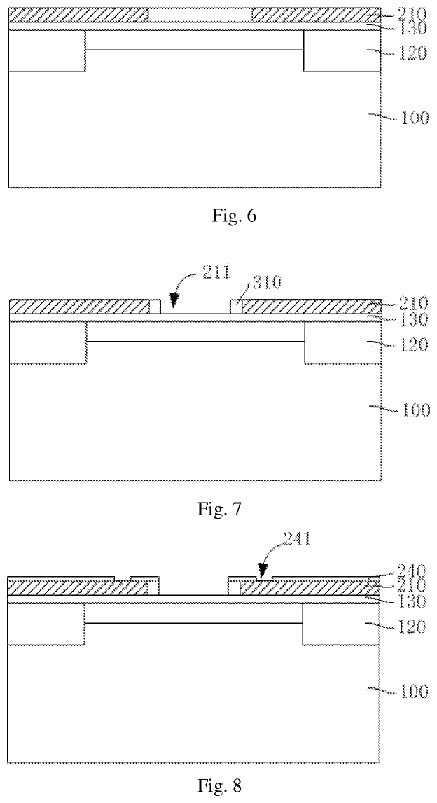

As shown in FIG. 6, when the insulating layer 130 is made of a material with high thermal insulation properties, the insulating layer 130 is then deposited only on the adhesion enhancement film. When the insulating layer 130 is made of silicon oxide or silicon nitride, the insulating layer 130 is then deposited on both the adhesion enhancement film and the support layer 110. The insulating layer 130 has a thickness of 20 nm to 200 nm. In the present embodiment, the insulating layer 130 is a silicon oxide layer. Accordingly, the insulating layer 130 is deposited over both the thermal conductivity enhancement layer 120 and the support layer 110.

As shown in FIGS. 6 to 13, next, in step S13, the plurality of thermocouple components 200 and absorption component 300 are formed. All the thermocouple components 200 are spaced apart from one another above the insulating layer 130 and the support layer 110, the thermocouple components 200 extend from above the thermal conductivity enhancement layer 120 towards the internal side of the internal annular wall. The absorption component 300 covers the support layer 110 and all the thermocouple components 200.

Specifically, this step includes the sub-steps as follows.

First of all, with continued reference to FIG. 6, a thin polycrystalline silicon layer is deposited on the insulating layer 130 using a LPCVD, atmospheric pressure chemical vapor deposition (APCVD), rapid thermal chemical vapor deposition (RTCVD) or PECVD process. The resulting thin polycrystalline silicon layer has a thickness of 300 nm to 5 μm.

N-type ions are implanted to regions where the first thermocouple arms 210 are to be formed, thereby forming the first thermocouple arms 210.

As shown in FIG. 7, an etching process is then carried out in a polycrystalline silicon region not affected by the implantation process, forming a first opening 211 internal to the first thermocouple arms 210, the first opening 211 exposes the insulating layer 130. The first opening 211 is formed as a combination of a plurality of inwardly tapered petal-like features, with a polycrystalline silicon region remaining around the first opening 211, which is not affected by the implantation process, finally providing the polycrystalline silicon layer 310.

As shown in FIG. 8, an intermediate dielectric layer 240 is formed over the first thermocouple arms 210 using a PECVD, RTCVD or LPCVD process, the intermediate dielectric layer 240 covers the first thermocouple arms 210, the insulating layer 130 and the polycrystalline silicon layer 310. The intermediate dielectric layer 240 may be made of silicon oxide or another material with low thermal insulation properties, and the intermediate dielectric layer 240 has a thickness of 20 nm to 500 nm.

After that, an etching process is performed on the intermediate dielectric layer 240, exposing the insulating layer 130 in the first opening 211. Moreover, second openings 241 are formed above the first thermocouple arms 210, the second openings 241 expose the underlying first thermocouple arms 210.

An electrically conductive material is then filled in the second openings 241, and an etching process is carried out to remove the electrically conductive material out of the first opening 211, thereby forming connecting posts 220.

When the connecting posts 220 are made of the same material as that filled in the first opening 211, in the above etching process, the electrically conductive material filled in the second openings 241 are also retained, thus simultaneously forming the connecting posts 220 and the light-interference and heat-guide layer 320. When the connecting posts 220 are made of a different material from that in the first opening 211, only the electrically conductive material in the second openings 241 are retained to form the connecting posts 220. The connecting posts 220 may be formed as plugs usually formed in the CMOS process, for example, in the form of TiN/Ti/W composite structures.

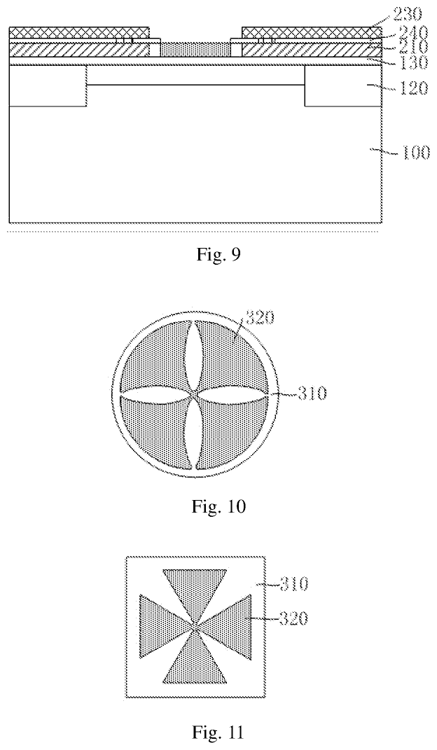

As shown in FIG. 9, a metal or polycrystalline silicon is deposited on the intermediate dielectric layer 240 using a physical vapor deposition (PVD) or chemical vapor deposition (CVD) process, and then an etching process is then carried out to form second thermocouple arms 230.

When the material deposited on the intermediate dielectric layer 240 is the same as that in the first opening 211 (e.g., Al), in the above etching process, the material deposited above the intermediate dielectric layer 240 and in the first opening 211 is retained, simultaneously forming the second thermocouple arms 230 and the light-interference and heat-guide layer 320. When the material deposited on the intermediate dielectric layer 240 is different from that in the first opening 211, only the second thermocouple arms 230 are formed from the etching process.

It should be noted that the material filled in the first opening 211 may be the same either as that of the second thermocouple arms 230, or as that of the connecting posts 220. Of course, in an alternative embodiment, the material filled in the first opening 211 may be different from both that of the second thermocouple arms 230 and that of the connecting posts 220. In this case, the material may be filled in the first opening 211 in a separate step to form the light-interference and heat-guide layer 320, which may precede the deposition of the intermediate dielectric layer 240.

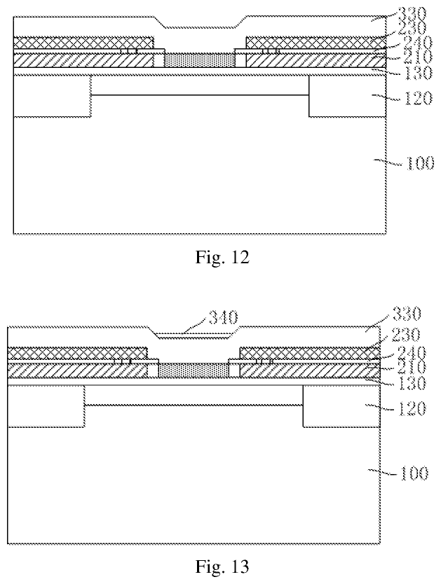

As shown in FIG. 12, an IR absorption layer 330 is deposited over the light-interference and heat-guide layer 320, the second thermocouple arms 230 and the intermediate dielectric layer 240 on the polycrystalline silicon layer 310. The IR absorption layer 330 may be a silicon nitride layer, or a silicon oxide/silicon nitride composite film. This can be accomplished by a passivation process commonly used in the CMOS process. The IR absorption layer 330 has a thickness greater than 1 μm.

As shown in FIG. 13, an enhanced absorption layer 340 is then formed on the IR absorption layer 330. The enhanced absorption layer 340 covers the IR absorption layer 330 above the polycrystalline silicon layer 310 and the light-interference and heat-guide layer 320. The enhanced absorption layer 340 is formed to reduce reflection and may be made of any of TiN, TiO₂, SiN, SiO, SiO₂, SiC and Al₂O₃, or a combination thereof. The enhanced absorption layer 340 has a thickness of 20 nm to 50 nm.

Subsequently, as shown in FIG. 2, a cavity 101 is formed in the substrate 100, the cavity 101 exposes the support layer 110. Specifically, a reticle may be formed by etching, which demarcates the thermal conductivity enhancement layer 120, and used to form a patterned mask layer on the backside, and the substrate 100 may be etched from the backside using the patterned mask layer as a mask to form the cavity 101. The resulting cavity 101 extends through the substrate 100 and exposes the support layer 110. Moreover, the cavity 101 is located internal to the internal annular wall of the first groove. An opening size of the cavity 101 at the backside is equal to a width defined by an internal annular wall of the thermal conductivity enhancement layer 120. An opening size of the cavity 101 at the front side is less than the width defined by the internal annular wall of the thermal conductivity enhancement layer 120.

### Example 2

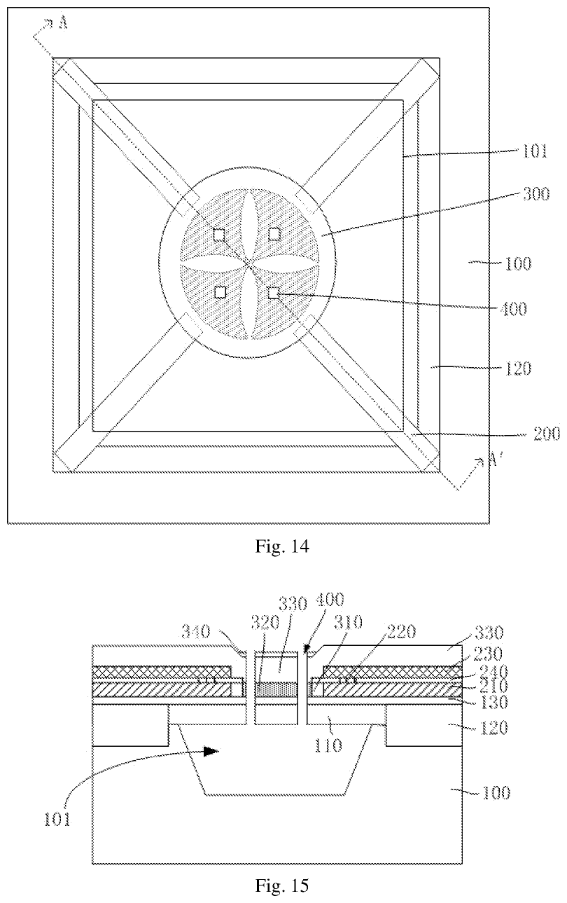

As shown in FIGS. 13 and 14, a second embodiment of the present invention differs from the first embodiment in including a blind cavity 101 located internal to a first groove, and the cavity 101 is on the same side as the first groove. The cavity 101 has an opening size less than a width defined by an internal annular wall of the first groove, and the first groove has a smaller depth than the cavity 101.

Specifically, an IR thermopile sensor according to the second embodiment includes a substrate 100, an annular first groove is formed in the substrate 100, and a cavity 101 is formed in the substrate 100 internal to an internal annular wall of the first groove. The cavity 101 is a blind cavity located internal to the first groove, and the first groove is provided therein with a thermal conductivity enhancement layer 120. The substrate 100 is provided thereon with a support layer 110, an insulating layer 130, a plurality of thermocouple components 200 and an absorption component 300. The support layer 110 resides above and closes the cavity 101. It also covers outer edges of the cavity 101 and the substrate 100 internal to the internal annular wall. The insulating layer 130 covers the thermal conductivity enhancement layer 120, and all the thermocouple components 200 are spaced apart from one another above the insulating layer 130 and the support layer 110, and all the thermocouple components 200 extend from above the thermal conductivity enhancement layer 120 towards the inside of the internal annular wall. The absorption component 300 covers the thermocouple components 200 and the support layer 110. Each thermocouple component 200 defines cold and hot ends in its direction of extension. The cold end is located above the thermal conductivity enhancement layer 120, and the hot end is located internal to the internal annular wall and connected to the absorption component 300. The thermal conductivity enhancement layer 120 is made of an electrically conductive material.

In order to form the cavity 101, a plurality of through openings 400 are formed evenly in the absorption component 300 above the cavity 101. The through openings 400 extend through the support layer 110, the insulating layer 130 and the absorption component 300. The polycrystalline silicon layer 310 and the light-interference and heat-guide layer 320 are arranged in the same layer, and in this layer, the through openings 400 extend through the light-interference and heat-guide layer 320.

According to this embodiment, the IR thermopile sensor may be made according to a method, which additionally includes steps for forming the through openings 400, prior to the formation of the cavity 101. Specifically, since the support layer 110, the insulating layer 130 and the absorption component 300 overlying the front side of the substrate 100 may be made of different materials, the formation of each of these layers may additionally include a step of forming through openings 400 therein, which expose the front side of the substrate 100. Specifically, first through openings may be additionally formed by etching in the support layer 110 during the formation of the first groove, and second through openings in the light-interference and heat-guide layer 320 during the formation of the light-interference and heat-guide layer 320. The second through openings are on top of the first through openings, and the first through openings are in communication with the second through openings.

Additionally, third through openings may be additionally formed by etching in the IR absorption layer 330 during the formation of the IR absorption layer 330. The third through openings are on top of the respective second through openings, and the first, second and third through openings sequentially communicate one with another.

Further, fourth through openings may be additionally formed by etching in the enhanced absorption layer 340 during the formation of the enhanced absorption layer 340. The fourth through openings are on top of the respective third through openings, and the first, second, third and fourth through openings sequentially communicate one with another and together constitute the through openings 400 that extend through the support layer, the insulating layer and the absorption component.

Finally, after the through openings 400 are formed, a dry or wet etching process may be carried out on the front side of the substrate 100 through the through openings 400 to form the cavity 101 in the substrate 100 internal to the internal annular wall of the first groove.

In summary, in the proposed IR thermopile sensor and method, the thermal conductivity enhancement layer can stabilize the temperature of the cold ends and reflect IR radiation, helping maintain the cold junctions at the same temperature as the ambient temperature. Thus, a temperature gradient can be more easily established across the hot and cold ends, resulting in improved responsivity. In addition, the interfering and heat-guide layer in the absorption component enables interference and coupling of reflected light with incident light, resulting in improved IR absorption performance. Further, the light-interference and heat-guide layer may define a particular pattern, which enables it to also guide heat to concentrate it at the hot ends of the thermocouples, helping reduce heat losses that may otherwise occur due to uniform heat conduction across, and heat radiation of, the absorption region. This means that the temperature of the hot junctions can rise at a faster rate and to a higher value at a given level of radiation intensity, contributing to increased responsivity and a shorter response time. The thermal conductivity enhancement layer and the interference and heat guide layer help provide the sensor with a good electromagnetic environment with reduced environmental noise. Stabilizing the cold ends at the ambient temperature also contributes to reducing thermal noise, helping reduce equivalent noise power and improve detectivity. The proposed method is based on the MEMS process and compatible with the CMOS process and does not require the use of any additional reticle. The only thing added is the formation and filling of the first groove, which results in a significant performance improvement almost without causing any increase in cost. Therefore, the present invention is more cost-effective and conducive to facilitate commercial large-scale production.

Further, it is to be noted that, as used herein, the terms “first”, “second”, and the like are only meant to distinguish various components, elements, steps, etc. from each other rather than indicate logical or sequential orderings thereof, unless otherwise indicated or specified.

It will be understood that while the invention has been described above with reference to preferred embodiments thereof, it is not limited to these embodiments. In light of the above teachings, any person familiar with the art may make many possible modifications and variations to the disclosed embodiments or adapt them into equivalent embodiments, without departing from the scope of the invention. Accordingly, it is intended that any and all simple variations, equivalent alternatives and modifications made to the foregoing embodiments based on the substantive disclosure of the invention without departing from the scope thereof fall within the scope.

1. An infrared thermopile sensor, comprising:
a substrate, wherein an annular first groove is formed in the substrate, the first groove provided therein with a thermal conductivity enhancement layer, and wherein the thermal conductivity enhancement layer is made of an electrically conductive material;
a support layer covering the substrate internal to an internal annular wall of the first groove;
an insulating layer covering the thermal conductivity enhancement layer;
a plurality of thermocouple components all spaced apart from one another above the insulating layer and the support layer, and the plurality of thermocouple components extending from above the thermal conductivity enhancement layer towards an internal side of the internal annular wall; and
an absorption component covering the support layer and all the thermocouple components.

2. The infrared thermopile sensor of claim 1, wherein the thermal conductivity enhancement layer is made of aluminum.

3. The infrared thermopile sensor of claim 1, wherein the thermal conductivity enhancement layer has a thickness greater than 2 μm, and the thermal conductivity enhancement layer has a width greater than 10 μm, or the thermal conductivity enhancement layer has a width greater than a cold junction width of the thermocouple components.

4. The infrared thermopile sensor of claim 1, wherein
the insulating layer is made of silicon carbide or aluminum nitride, wherein the insulating layer covers only the thermal conductivity enhancement layer, or
the insulating layer is made of silicon oxide or silicon nitride, wherein the insulating layer covers both the thermal conductivity enhancement layer and the support layer.

5. The infrared thermopile sensor of claim 1, wherein each of the thermocouple component comprises:
a first thermocouple arm formed above the insulating layer and the support layer, and the first thermocouple arm extending from above the thermal conductivity enhancement layer towards the internal side of the internal annular wall;
an intermediate dielectric layer formed on the first thermocouple arm;
a second thermocouple arm formed on the intermediate dielectric layer; and
a connecting post extending through the intermediate dielectric layer, an end of the connecting post proximal to the first thermocouple arm being in contact with the first thermocouple arm and an end of the connecting post proximal to the second thermocouple arm being in contact with the second thermocouple arm.

6. The infrared thermopile sensor of claim 5, wherein the absorption component comprises:
a polycrystalline silicon layer formed on the support layer, the polycrystalline silicon layer internal to all the first thermocouple arms, the polycrystalline silicon layer being in contact with all the first thermocouple arms, and the intermediate dielectric layer covering the polycrystalline silicon layer;
a light-interference and heat-guide layer formed on the support layer, the light-interference and heat-guide layer internal to all the first thermocouple arms, the light-interference and heat-guide layer surrounded by the polycrystalline silicon layer;
an infrared absorption layer covering the light-interference and heat-guide layer, the second thermocouple arms and the intermediate dielectric layer over the polycrystalline silicon layer; and
an enhanced absorption layer covering the infrared absorption layer over the polycrystalline silicon layer and the light-interference and heat-guide layer.

7. The infrared thermopile sensor of claim 6, wherein
the first groove is a circular, elliptical or polygonal ring,
wherein the light-interference and heat-guide layer is provided as a combination of a plurality of petal-like elements, which are centered at a center of the first groove and each has a width gradually increasing in a direction away from the center.

8. The infrared thermopile sensor of claim 7, wherein the light-interference and heat-guide layer is spaced from the thermocouple components at a distance less than 10 μm, and where the light-interference and heat-guide layer has a thickness of 100 nm to 1 μm.

9. The infrared thermopile sensor of claim 6, wherein the light-interference and heat-guide layer is made of a metal material or polycrystalline silicon.

10. The infrared thermopile sensor of claim 1, wherein the substrate has a front side and a backside opposite to the front side, wherein the substrate internal to the internal annular wall of the first groove defines a cavity,
the cavity in the form of a through opening extending through the substrate and exposing the support layer on the front side, the cavity having an opening size at the backside equal to a width defined by an internal annular wall of the thermal conductivity enhancement layer and an opening size at the front side less than a width defined by the internal annular wall of the first groove.

11. The infrared thermopile sensor of claim 1, wherein the substrate has a front side and a backside opposite to the front side, wherein the substrate internal to the internal annular wall of the first groove defines a cavity,
the cavity in the form of a blind cavity and on the front side along with the first groove, the cavity closed by the support layer, the cavity having a larger depth than the first groove, the cavity having an opening size less than a width defined by the internal annular wall of the first groove.

12. The infrared thermopile sensor of claim 10, wherein the thermal conductivity enhancement layer is spaced from the cavity at a distance greater than 5 μm.

13. The infrared thermopile sensor of claim 11, wherein the absorption component over the cavity is evenly provided therein with a plurality of through openings, the plurality of through openings extending through the support layer, the insulating layer and the absorption component.

14. A method of manufacturing the infrared thermopile sensor of claim 1, comprising the steps of:
providing a substrate, wherein an annular first groove is formed in the substrate, and a support layer is formed on the substrate internal to an internal annular wall of the first groove;
forming a thermal conductivity enhancement layer and an insulating layer, the thermal conductivity enhancement layer filling up the first groove, the insulating layer formed on the thermal conductivity enhancement layer, wherein the thermal conductivity enhancement layer is made of an electrically conductive material; and
forming a plurality of thermocouple components and an absorption component, all the thermocouple components spaced apart from one another above the insulating layer and the support layer and extending from above the thermal conductivity enhancement layer towards an internal side of the internal annular wall, the absorption component covering the support layer and all the thermocouple components.

15. The method of manufacturing the infrared thermopile sensor of claim 14, further comprising, after the plurality of thermocouple components and the absorption component are formed,
forming a cavity in the substrate, the cavity exposing the support layer.
